(19) United States
(12) Patent Application Publication
(10) Pub. No.: US 2019/0115883 A1
(43) Pub. Date: Apr. 18, 2019

(54) ANALOGUE SIGNAL OUTPUT CIRCUIT

(71) Applicants: Mitsutoshi Sugawara, Yokohama-shi (JP); Satishi Kawashima, Tokyo (JP)

(72) Inventors: Mitsutoshi Sugawara, Yokohama-shi (JP); Satishi Kawashima, Tokyo (JP)

(21) Appl. No.: 15/731,587

(22) PCT Filed: Jan. 9, 2015
(86) PCT No.: PCT/JP2015/050561

§ 371 Date: Nov. 26, 2018

(51) Int. Cl. H03F 3/24; H04L 27/04; H04L 27/12; H03F 3/217; H04L 27/20

(52) U.S. Cl. CPC H03F 3/24; H04L 27/04; H04L 27/2003; H03F 3/2176; H04L 27/12

(57) ABSTRACT

The present application provides a high-efficiency low-distortion power output circuit and a high-frequency low-distortion power output circuit including a modulator, these power output circuits being configured so that an input digital value can be directly connected to an antenna. In the power output circuit, one ends of a plurality of physical elements are commonly connected to an output terminal. The other ends of the physical elements are each switchably connected to a first or second reference voltage source via a corresponding one of switching elements. This circuit is characterized by having a switch control circuit. The switch control circuit performs such control that a predetermined number of switching elements are alternately operated while the remaining number of switching elements are connected to any of the reference voltage sources or a switching element configured for interconnection is added. The power output circuit including the modulator has a switch control circuit configured to control the predetermined number of switching elements according to a digital baseband signal.

### TECHNICAL FIELD

The present invention relates to an analogue signal power output circuit. Specifically, the present invention relates to a high-efficiency distortionless analogue power signal output circuit suitable for a high frequency.

### BACKGROUND ART

The age of digital communication has been currently brought. However, various types of typical analogue power amplifier circuits have been, as usual, used for high-speed high-frequency power signal output circuits.

FIG. 2 illustrates an example of a general high-frequency transmission circuit. An input is a digital signal called a digital baseband. Two signals called I and Q as digital baseband outputs are converted back into analogue signals by DA conversion. Then, these signals are modulated using a carrier wave, and are added up. The resultant signal is power-amplified via a band-pass filter, and then, is output to an antenna. That is, all of these steps are analogue processing.

The following method has been used sometimes. Digital modulation is performed using a relatively-low intermediate frequency in a digital baseband. The resultant output is converted back into analogue by a DA converter, and then, is frequency-converted. The resultant signal is power-amplified via a band-pass filter, and then, is supplied to an antenna. Specifically, in a recent general method for image removal, a digital modulator produces two signals of I and Q. These signals are frequency-converted, and then, are added up. This is a method in which “modulation” of FIG. 2 is replaced with “frequency conversion,” and a circuit itself for this method is equivalent to the circuit of FIG. 2.

The inventor(s) of the present application aims to provide a power output circuit using a digital baseband signal as an input to allow direct output to an antenna as illustrated in FIG. 1.

### CITATION LIST

### Patent Literature

### Patent Literature 1: JP-A-2013-187678 “Output Circuit, Method of Controlling Output Circuit, and Semiconductor Device”

This literature describes a wired communication analogue output circuit including resistors and switches as the invention of the inventor(s) of the present application et al. This circuit is configured to directly output a multivalued digital signal.

Patent Literature 2: U.S. Pat. No. 3,919,656 “High Frequency Tuned Switching Power Amplifier”

This literature relates to an E-class amplifier. This is a single-amplitude power output circuit including capacitive inductors and switches.

Non-Patent Literature 1: D. T. Corner and D. S. Korth, “Synthesis of low-spur GHz sinusoids using a 4-bit D/A converter,” Frequency Control Symposium, 2008 IEEE International, p. 750-752

This literature describes an example of a technique requiring an ultrahigh-speed DA converter with 10 Gsps at 4 bit, but producing a signal digitally close to a sinusoidal wave. This is also utilized in the present application.

FIG. 9 of Patent Literature 1 illustrates an output circuit illustrated in FIG. 5 of the present application. An input of this circuit is a digital signal, and this circuit includes switching elements and resistors. This circuit is characterized in that an output impedance is close to 100Ω (50Ω at each single end) in differential operation defined according to communication standards and that a 2-bit digital signal, i.e., a 4-value digital signal, is output for pre-emphasis processing. For enhancing noise immunity, differential output is generally employed.

FIG. 3 of Patent Literature 2 illustrates an output circuit illustrated in FIG. 4 of the present application. By an input digital signal with a carrier frequency, switching elements including bipolar transistors are switched. The signal is transmitted to a network circuit formed of a network circuit including a capacitor and an inductor. The network circuit cancels out a capacitive reactance and an inductive reactance of the inductor, by resonance.

### SUMMARY OF INVENTION

### Problems to be Solved by the Invention

The inventor(s) of the present application has first considered that “the typical wired communication pulse output circuit with a pre-emphasis function as illustrated in FIG. 5” is used as a “modulation plus power amplification” shown in FIG. 1. This circuit generates a digital signal power output by using the resistors and the switching elements. However, such an output is basically a square-wave output. By Fourier series expansion, a square wave can be represented as follows:

2/π){sinθ+(⅓)sin3θ+(⅕)sin5θ+( 1/7)sin7θ+. . . }

Many high-order harmonics such as a ⅓ harmonic, i.e., a −9.5 dB third harmonic, and a ⅕ harmonic, i.e., a −14 dB fifth harmonic, are contained. According to common laws and communication standards such as the Radio Law, emission of high-order harmonics is strictly limited. For this reason, the square-wave output cannot be used as a wireless communication output. The inventor(s) of the present application provides the invention solving such a problem.

Although described later, a DA converter type circuit using resistors has a disadvantage that a power efficiency is an extremely-low efficiency which is about the half of that of an A-class amplifier. The inventor(s) of the present application provides the invention practicable with an improved power efficiency.

In wired communication as in an application example of Patent Literature 1, harmonics might be allowed. Note that the pre-emphasis described in this literature is a compensation boosting higher frequency region. This processing has an adverse effect on countermeasures for eliminating harmonics in a wireless high-frequency power output circuit as an object of the present application. For this reason, Patent Literature 1 does not contain contents suggesting the invention of the present application.

Next, use of the E-class amplifier circuit illustrated in FIG. 4 of Patent Literature 2 was contemplated. By a quality factor (hereinafter referred to as “Q”) of such a resonance circuit, a harmonic component is reduced to substantially 1/Q of a primary filter. This is not an issue as long as requirements of the laws and communication standards such as the Radio Law can be satisfied. In fact, stricter harmonic attenuation is, however, required in many cases. For this reason, a further filter needs to be provided at a later stage.

The inventor(s) of the present application provides the invention solving such a problem.

Moreover, it is a well-known disadvantage of the E-class amplifier circuit that an amplitude cannot be changed with a high efficiency being maintained. That is, there is a disadvantage that a carrier wave and waves without a change in a carrier amplitude, such as a frequency-modulated wave, a phase-modulated wave, and telegraph can only be outputted with a high efficiency. The inventor(s) of the present application provides the invention relating to the power output circuit of an analogue amplitude-modulated wave in addition to above waves.

### Solutions to the Problems

The present application relates to “a power output circuit and a power output circuit including a modulator, each power output circuit including a power output circuit with a plurality of physical quantity elements and a plurality of switching elements configured to switch the physical quantity elements and a switch control circuit configured to control the switching elements.” The present application includes “the power output circuit and the power output circuit including a modulator, each power output circuit being characterized in that the switch control circuit generates a fundamental wave and reduces at least a third harmonic.”

Moreover, the present application includes “the power output circuit and the power output circuit including the modulator, each power output circuit having a switching element configured to connect between physical quantities, and a control circuit of such a switching element” so that power saving can be specifically realized in the case of using a resistance as the physical quantity.

Further, the present application includes “switch control for realizing variable output power and power saving by means of a resonance inductance” in the case of using a capacitance as the physical quantity.

### Effects of the Invention

Although not described in detail, the high-efficiency power output circuit and the high-efficiency power output circuit including the modulator can be realized with excellent harmonic reduction according to the invention of the present application.

Thus, the power output circuit including the modulator and configured to directly output to an antenna from a low-frequency digital baseband signal can be realized. Consequently, the number of components and a cost can be significantly reduced.

According to the invention of the present application, a transistor used only in an ON state or an OFF state is used as the switching element while no transistor used in a linear region is necessary. Thus, there is no portion causing analogue distortion, leading to an advantageous effect of easily realizing a distortionless power output circuit,

### DESCRIPTION OF EMBODIMENTS

### First Embodiment

FIG. 5a illustrates a circuit diagram of a first embodiment of the present application.

In this circuit, one end of each of physical quantity elements E₁, E₂ is connected to a reference voltage V_{ref} or a reference point GND thereof via a corresponding one of switching elements S₁, S₂ according to a digital input Ii for controlling such a switch. GND may be replaced with V_{ref}. This circuit is configured such that an output is taken from a point O₁ commonly connected to the other ends of E₁, E₂, and then is provided to a load R_{L}. This circuit is characterized in that the switching elements S₁, S₂ are controlled such that voltage waveforms V₁, V₂ as illustrated in FIG. 5b are obtained. V₁ is a voltage obtained in such a manner that the switching element S₁ is connected to V_{ref} at a first half cycle and is connected to GND at a subsequent half cycle. V₂ is a signal obtained in such a manner that such a voltage is delayed by π/3 radian=60° at a phase shifter S_{ft}. These power sources V₁, V₂ with the switched pulse-shaped waveforms can be used to rewrite FIG. 5a to FIG. 5c.

Moreover, in this example, E₁ and E₂ have an equal physical quantity.

A resistance value and a capacitance value are broadly used as the physical quantity. However, the physical quantity is not limited to these values, and may be an inductance, a current source, etc.

In the case of using the resistance value as the physical quantity, it is not avoidable that a capacitor is inserted in parallel with a load (not shown) to form a low-pass filter.

In the case of using the capacitance value as the physical quantity, it is not avoidable, as in Patent Literature 2, that for cancelling out a capacitive reactance, an inductance is inserted in series with a load (not shown) to generate resonance.

A MOS transistor is broadly used as the switching element, but the switching element is not limited to the MOS transistor.

By equivalent conversion of FIG. 5c according to the Thevenin's theorem, FIG. 5d is obtained. In this circuit, a voltage source Vₜ is a load open end voltage represented as follows:

Vₜ=(V₁+V₂)/2

By calculation using the waveforms of FIG. 5b, a waveform of FIG. 5e is obtained.

Moreover, Eₜ is a parallel value between the physical quantities E₁, E₂.

This waveform is nothing less than a DC-shifted waveform obtained provided that t₁=⅓T, t₂=⅙T in FIG. 2 of Non-Patent Literature 1.

A result obtained by Fourier series expansion of this waveform is as follows:

(2/π){1+sinθ+(−⅕)sin5θ+(− 1/7)sin7+( 1/11)sin11θ+. . . }

A third harmonic is cancelled out.

In the case of using the resistance as the physical quantity, only a ⅕ harmonic, i.e., −14 dB fifth harmonic, is contained, and higher-order harmonics as compared to the fifth harmonic are much smaller. Thus, as illustrated in FIG. 5f, a capacitor C_{L} indicated by a dashed line is connected in parallel with the load R_{L} to form a primary low-pass filter. Only with this configuration, the fifth harmonic is further attenuated by about −14 dB, for example. Consequently, a carrier-to-noise ratio C/N of about 28 dBc in total can be obtained. Higher-order harmonic components as compared to the fifth harmonic are much smaller.

As necessary, a capacitor for DC component blocking may be inserted (not shown).

As illustrated in FIG. 5g, in a case where the capacitance is used as the physical quantity and an inductor L_{L} is added to generate resonance, only a 1/Q fifth harmonic with 1/25=−28 dB is further contained. For example, when Q=10, C/N=48 dBc. Higher-order harmonics as compared to the fifth harmonic are much smaller.

When the harmonics can be removed to such an extent, a direct output via an antenna might be made while complying with laws and standards. That is, a power output circuit of FIG. 1 can be realized. Even if such a circuit is insufficient, such insufficiency can be, in most cases, solved only by post-positioning of a simple filter. This provides a sufficient industrial merit.

As necessary, the capacitor for DC component blocking may be inserted (not shown).

In FIG. 5a, it is industrially important to cancel out a third harmonic by a combination of square waves. In the present embodiment, only two elements with the equal physical quantity are used, and other elements for linear operation are not used. Thus, distortion is extremely low.

Note that the method for producing a switch control signal with a delay of π/3 radian=60° will be described as an example. For example, a clock signal with a sixfold frequency is generated in advance, and then, is divided to ⅙ frequency. In this manner, an accurate phase delay of π/3 radian=60° can be produced. Alternatively, a phase difference of π/3 radian=60° can be easily produced in such a manner that a ring oscillator is formed such that three delay circuits are placed in a ring and that outputs form various output points.

The switches can be controlled in every π/4 radian=45° . In this case, the third harmonic in Fourier series expansion can be canceled using 0, 1, 1+0.404, 1, 0, −1, −1 −0.404, −1, 0. This can be met by preparation of a physical quantity element with a size of 0.404 and addition of the switch control of adding such a physical quantity element. Similarly, the switch control can be generally realized in every π/m radian (m >2).

In FIG. 5a, an output amplitude is unambiguously determined according to the reference voltage source V_{ref}, and therefore, is constant in principle. That is, only a carrier wave with a constant carrier wave output amplitude is available for a frequency-modulated wave, a phase-modulated wave, and a telegraph wave according to ON/OFF of the carrier wave.

The reference voltage source V_{ref} is replaced with a voltage obtained by DA conversion of a relatively-low-frequency baseband signal, and as a result, a high-frequency signal with an amplitude corresponding to such a voltage can be directly generated. That is, an amplitude-modulated wave and a double-sideband-modulated wave can be output.

However, a baseband DA converter and/or A-class operation of a buffer amplifier for DA converter needs to be performed. For this reason, this configuration should be power-hungry, and is not efficient. An invention with an enhanced efficiency will be described below as countermeasures against the above-described issue.

### Second Embodiment

FIG. 6a illustrates a circuit diagram of a second embodiment of the present application. In this circuit, N physical quantity elements E₁ to E_{N} can be each switched to either of a reference power source V_{ref} or a reference point GND thereof by a corresponding one of switching elements S₁ to S_{N}. In this circuit, commonly-connected other ends of the physical quantity elements serve as an output. Description of the same elements as those of FIG. 5a will not be repeated.

First, all of the physical quantity elements have the same physical quantity value Eᵤ. The following case is assumed. Of the N physical quantity elements, N/2+x physical quantity elements E1 to E_{N/2+2x} are connected to the V_{ref} side, and the remaining N/2−x physical quantity elements E_{N/2+2x+1} to E_{N} are connected to the GND side. When FIG. 6a is rewritten to FIG. 6b by means of a power source according to a switch state, and is converted into a circuit of FIG. 6c by application of the Thevenin's theorem, an open-end voltage Vₜ is represented as follows:

Vₜ=V_{ref}(N/2+x)/N=V_{ref}(0.5+x/N)

Moreover, an equivalent physical quantity Et is constantly a value when N elements with Eᵤ are connected in parallel. For example, when N=64 and x=−31 to +31, this is a normal 6-bit DA converter. An optional output voltage of 0 to V_{ref} can be obtained with a resolution of 6 bit according to a digital value x.

First, in the above-described example, 2x physical quantity elements E₁ to E₂ₓ are, at high speed, switched to V_{ref} at a first half cycle, and is switched to GND at a subsequent half cycle. The remaining N/2−x physical quantity elements E₂ₓ₊₁ to E_{N/2+2x} are constantly connected to V_{ref}. The N/2−x physical quantity elements E_{N/2+2x+1} to E_{N} are constantly connected to GND. With this configuration, a high-frequency power output with an amplitude of ±V_{ref}·x/N can be obtained as the open-end output voltage Vₜ. This is output to a load R_{L} according to the Thevenin's theorem. In this case, a square wave is output to the load R_{L}. Thus, for forming a low-pass filter, connection of a capacitor C_{L} is recommended.

Note that instead of the square-wave-shaped output, an optional sinusoidal high-frequency output can be obtained in such a manner that a digitalized sinusoidal signal is sequentially provided for the number x of elements, for example. An optional modulated wave can be also output by using, as x, a value obtained by desired modulation calculation in a digital domain.

FIG. 6d illustrates an example of a circuit in a case where the physical quantity elements of the circuits of FIGS. 6a to 6c are resistors. The capacitor C_{L} forming the low-pass filter is added in parallel with the load R_{L}. This circuit is a DA converter itself. When 50Ω is selected as the equivalent physical quantity Eₜ, this circuit can be directly connected to standard transmission path and measuring instrument. The equivalent physical quantity Eₜ can be set according to an antenna characterisitc impedance, such as 75Ω, 200Ω, or 300Ω.

FIG. 6d has a disadvantage that a power efficiency is low. According to simple calculation, when a load resistance is R_{L}, the equivalent physical quantity Eₜ is equal to R_{L}, and a voltage of V_{ref} is applied, the maximum V_{ref} peak-to-peak sinusoidal wave is output at an open end. Thus, upon connection of a matched load, V_{ref}/2 pp is obtained, and {(V_{ref}/2)/(2sqrt(2))}²/R_{L}=V_{ref}²/32R_{L} is, in effective value equivalent, obtained as the maximum output power (an AC component) transmitted to the load. For example, the output power in the case of V_{ref}=1V and R_{L}=50 Ω is 0.625 mW =−4 dBm.

On the other hand, upon no signal output, i.e., x=0, DC current flows from V_{ref} to GND although AC output power is zero. In an equivalent manner, a first resistor 2R_{L} is connected to V_{ref}, and a second resistor 2R_{L} is connected to GND. Thus, a useless static power of V_{ref}²/4R_{L} is consumed. In fact, this leads to eight times higher than the maximum output power.

In the case of LSI of an analogue circuit, a differential configuration is generally employed for reducing noise influence. In fact, power output circuits of Patent Literature 1 and FIG. 3 also have a differential configuration.

A new circuit overcoming the disadvantage of FIG. 6d in the case of the differential configuration will be proposed as FIG. 6e.

First, in FIG. 6e, physical quantity elements are resistors as in FIG. 6. 2x physical quantity elements E₁ to E₂ₓ connected to a positive output O₁ are, at high speed, switched to V_{ref} at a first half cycle, and are switched to GND at a subsequent half cycle. The remaining N−2x physical quantity elements E₂ₓ₊₁ to E_{N} are constantly in a physical quantity element interconnection. Similarly, 2x physical quantity elements E₁′ to E₂ₓ′ connected to a negative output O₂ are switched to GND at the first half cycle, and are switched to V_{ref} at the subsequent half cycle. The remaining N/2−x physical quantity elements E_{2X+1}′ to E_{N}′ are constantly in inter-resistor connection.

With this configuration, the potential of each portion connected between the physical quantity elements via the switching elements S₂ₓ₊₁ to S_{N}, S₂ₓ₊₁′ to S_{N}′ is an average value of O₁ and O₂. Because of differential operation, such an average value is equal to an average value of V_{ref} and GND, i.e., a midpoint potential V_{ref}′. V_{ref}′=V_{ref}/2 is satisfied.

The potential of each portion connected between the resistors is equal to the midpoint potential V_{ref}′. Thus, a circuit configured such that all of these portions are interconnected with each other and are connected to a reference power source of V_{ref}/2 as in FIG. 6f is equivalent to the above-described circuit. This is because the portions with the same potential, i.e., the portions with a zero-potential difference, are connected together, and therefore, no current flows through this connection according to the Ohm's law and no state change is brought due to the presence or absence of this connection. The upper half of FIG. 6f as a positive side and the lower half of FIG. 6f as a negative side are equivalent respectively to two power output circuits connected between V_{ref} and V_{ref}′ and between V_{ref}′ and GND.

On the other hand, in the circuits of FIGS. 6e and 6f, AC output power is zero upon no signal output, i.e., x=0. Needless to say, a potential difference between positive and negative output terminals O₁ and O₂ is zero. Thus, the potential difference is zero between the resistors connected via the switching elements S₂ₓ₊₁ to S_{N}, S₂ₓ₊₁′ to S_{N}′. No current flows between these resistors, and no useless static power is consumed. There is an advantage that a power efficiency can be amazingly improved as compared to the example described in paragraph 0024.

Moreover, in FIG. 6e, control is collectively performed for an even number of switches in increments of 2x for convenience of description. In this example, when 2x is replaced with y, control for y switches and N/2−y switches can be performed, and the y switches can be controlled one by one. That is, there is an advantage that the number of switches can be reduced to half. Although not described in the following embodiments, similar conversion can be made in the case of performing the switch control in increments of 2x, needless to say.

Note that no current eventually flows through each portion connected between the switching element S₂ₓ₊to S_{N} and the switching element S₂ₓ₊₁′ to S_{N}′. Thus, this example is not limited to the state in which the V_{ref}′ terminal is connected to the reference power source V_{ref}/2 as in FIG. 6f. A state in which the V_{ref}′ terminal remains open is equivalent to the above-described state. Alternatively, a state in which the V_{ref}′ terminal is bypassed by an added bypass capacitor and a state in which the V_{ref}′ terminal is connected to the reference power source V_{ref}/2 via a great resistor are also equivalent to the above-described state.

Moreover, in FIGS. 6d to 6f, one end of each single resistor is connected to V_{ref} or GND via the switching element, for example. Instead, switching may be performed such that a plurality of resistors are connected to V_{ref} or GND or are opened via different switching elements. In this case, there is an advantage that through-current upon switching can be reduced.

FIG. 6g illustrates an example of a circuit in a case where the physical quantity elements of the circuits of FIGS. 6a to 6c are capacitors. A resonance inductor is inserted in series with the load R_{L}. As will be clearly seen from the equivalent circuit of FIG. 6c, this circuit is a circuit including an N gradation voltage source, a resonance circuit having an equivalent capacitor and an inductor, and a load T_{L}. For example, when N=1024, such a circuit is equivalent to a 10-bit DA converter, and can make, with a resolution of about 0.1%, an optional analogue output including a sinusoidal wave and a modulated wave. Moreover, such an equivalent circuit is the same as an E-class circuit, and it can be expected that the equivalent circuit exhibits an extremely-high efficiency.

Based on the above-described discussion, FIG. 6g is nothing less than an output of an E-class amplifier super-multilevel with a high efficiency, such a super-multilevel output having never been possible to obtain. This means a lot to an industrial area, and means that high-efficiency low-distortion products can be produced in a broad area including not only wireless communication but also wired communication and DC/AC converters, for example.

In paragraph 0020, the number x of switching elements to be turned ON/OFF has been described. Actual switch control can be easily realized in such a manner that the signal to be switched in every half cycle as described above is gated by an output of a well-known circuit called a thermometer decoder configured to make, to a high level, the number of signals according to the number x of elements. In addition, the following methods are conceivable, for example. As another example, switching element control terminals are collectively connected in increments of one, two, four, eight, . . . terminals in advance, and then the signal to be switched in every half cycle is gated in terms of a binary code of x. As the other example, physical quantity elements with a size corresponding to a single element, a size corresponding to two elements in parallel, a size corresponding to four elements in parallel, and a size corresponding to eight elements in parallel are produced in advance, and then, these elements are switched by switching elements controlled in terms of the binary code of x. A combination of these methods and other methods may be employed, and the present application is not limited to the methods described as examples.

### Third Embodiment

Next, a power output circuit including a modulator will be described as a third embodiment of the present application with reference to FIG. 7a. FIG. 7a is, as a circuit diagram, substantially the same as that of FIG. 6a. Note that the method for controlling switching elements S₁ to S_{N} has the following features.

First, in FIG. 7a, x physical quantity elements Eₓ₊₁ to E₁ are, with a high-speed carrier wave, switched to V_{ref} at a first half cycle, and are switched to GND at a subsequent half cycle. Other x physical quantity elements E₂ₓ to Eₓ₊₁ are similarly switched with a signal obtained in such a manner that the high-speed carrier wave is delayed by π/3 radian=60°. The remaining N/2−x physical quantity elements E₂ₓ₊₁ to E_{N/2+2x} are constantly connected to V_{ref}. N/2−x physical quantity elements E_{N/2+2x+1} to E_{N} are connected to GND.

With this configuration, a high-frequency power output with an amplitude of ±V_{ref}·x/N can be obtained as an open-end output voltage Vₜ.

As described above, when an output waveform is subjected to Fourier series expansion, a third harmonic is cancelled out, and fifth, seventh, eleventh, . . . harmonics are contained. Thus, a harmonic attenuation degree similar to that described in 0013 can be obtained. When a relatively-low frequency baseband signal is provided for the number x of elements, an amplitude-modulated wave (precisely, a double-sideband-modulated wave) of this signal by means of the high-speed carrier wave is obtained.

This circuit is characterized in that this circuit is a high-frequency power output circuit also having a modulator function. That is, as illustrated in FIG. 7a, a relatively-low-speed digital baseband signal is input as a digital value x. Then, 2x switches set according to such a value are alternately controlled at high speed. This can realize a compact power output circuit allowing direct output to an antenna.

In this embodiment, FIGS. 7d to 7e using at least a resistance as a physical quantity or FIGS. 7f to 7g using a capacitance as the physical quantity can be used. Note that the physical quantity is not limited to above. Moreover, a high-efficiency power output circuit as in the second embodiment can be realized in such a manner that every N−2x switches S₂ₓ₊₁ to S_{N}, S₂ₓ₊₁′ to S_{N}′ are, using circuits of FIGS. 7e and 7g, not connected to V_{ref} and V_{ref}′, but are interconnected with each other.

In fact, when switch operation described in 0032 has been finely analyzed in the differential circuits of FIGS. 7e and 7g, it has been found that the x physical quantity elements Eₓ₊₁ to E₁ are, in a range of 0 to π/3 radian, connected to V_{ref} and the other x physical quantity elements E₂ₓ to Eₓ₊₁ are connected to GND. It is obvious that connection between the physical quantity elements E₂ₓ to E₁ and E₂ₓ′ to E₁′ is changed to interconnection by control of the switching elements S₁ to S_{2X} during this period, and therefore, current flowing through these physical elements can be zero during this period. The same applies to a period of π to 4π/3.

As described above, more power consumption reduction can be realized by more detailed switch control.

As described in 0017, a clock signal with a sixfold frequency is, for example, generated in advance, and then, is subjected to ⅙ frequency division. In this manner, a signal with a phase delay of π/3 radian=60° can be produced. From this signal, a switch control signal can be produced according to a simple logic. Alternatively, a ring oscillator configured such that three delay circuits are arranged in a ring pattern may be used.

Although not specifically shown in the figure, elements configured to perform high-speed switching between the reference power source V_{ref} and GND may be, in addition to above, provided as a switch control method, for example. Further, these elements may be collectively connected via x switching elements to be relatively slowly switched with a baseband signal, and then, may be connected to elements to be switched at high speed.

With this configuration, there is an advantage that the switches to be operated at high speed can be limited.

As described in 0002, the technique of modulating, with a high-speed signal with a phase difference of π/2 radian=90°, two signals called I and Q in FIG. 2 has been broadly used.

This can be realized in such a manner that two “power output circuits including modulators” as in the third embodiment of the present application are connected in parallel to perform switch control for each of I and Q. Note that the contents of this circuit include a group of series connections of 2N (4N in the case of differential operation) physical elements and switches. Thus, the two “power output circuits including the modulators” may be collectively produced together to accurately perform control for the number of switches of each circuit.

### INDUSTRIAL APPLICABILITY

According to the invention of the present application, a high-efficiency power output circuit with less harmonic interference can be configured to defy conventional wisdom without using a transistor configured to operate in a linear region. Moreover, few elements causing distortion are provided, and therefore, distortion is extremely low.

With this configuration, necessity for a power amplifier circuit employing analogue operation and having been required so far can be eliminated. Specifically, an output of wireless equipment equipped with the power output circuit of the invention of the present application can be directly connected to an antenna, leading to significant cost down.

### BRIEF DESCRIPTION OF THE DRAWINGS

FIG. 1 illustrates an example of a block diagram of a wireless transmitter employing the present application;

FIG. 2 illustrates an example of a block diagram of a prior typical wireless transmitter;

FIG. 3 illustrates an example of a prior typical wired communication pulse output circuit having a pre-emphasis function;

FIG. 4 illustrates an example of a prior typical E-class power amplifier circuit;

FIG. 5 illustrates a first embodiment of the present application, FIG. 5a illustrates a basic circuit diagram, FIG. 5b illustrates an internal waveform applied by switching, FIG. 5c illustrates an equivalent circuit using a power source, FIG. 5d illustrates an equivalent circuit employing the Thevenin's theorem, FIG. 5e illustrates an internal waveform employing the Thevenin's theorem, FIG. 5f illustrates an example using resistors, and FIG. 5g illustrates an example using capacitors;

FIG. 6 illustrates a second embodiment of the present application, FIG. 6a illustrates a basic circuit diagram, FIG. 6b illustrates an equivalent circuit using a power source, FIG. 6c illustrates an equivalent circuit employing the Thevenin's theorem, FIG. 6d illustrates an example using resistors, FIG. 6e illustrates a high-efficiency example using resistors, FIG. 6f illustrates another high-efficiency example using resistors, and FIG. 6g illustrates a high-efficiency example using capacitors and allowing variable output and power consumption reduction; and

FIG. 7 illustrates a third embodiment of the present application, FIG. 7a illustrates a basic circuit diagram, FIG. 7b illustrates an equivalent circuit using a power source, FIG. 7c illustrates an equivalent circuit employing the Thevenin's theorem, FIG. 7d illustrates an example using resistors, FIG. 7e illustrates a high-efficiency example using resistors, FIG. 7f illustrates another high-efficiency example using resistors, and FIG. 7g illustrates a high-efficiency example using capacitors and allowing variable output and power consumption reduction.

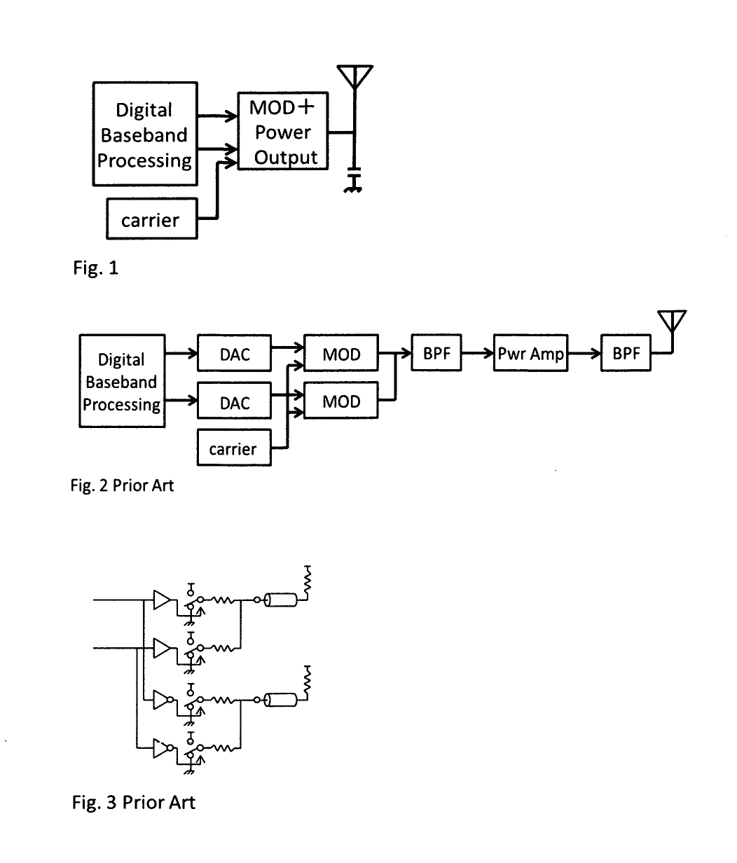

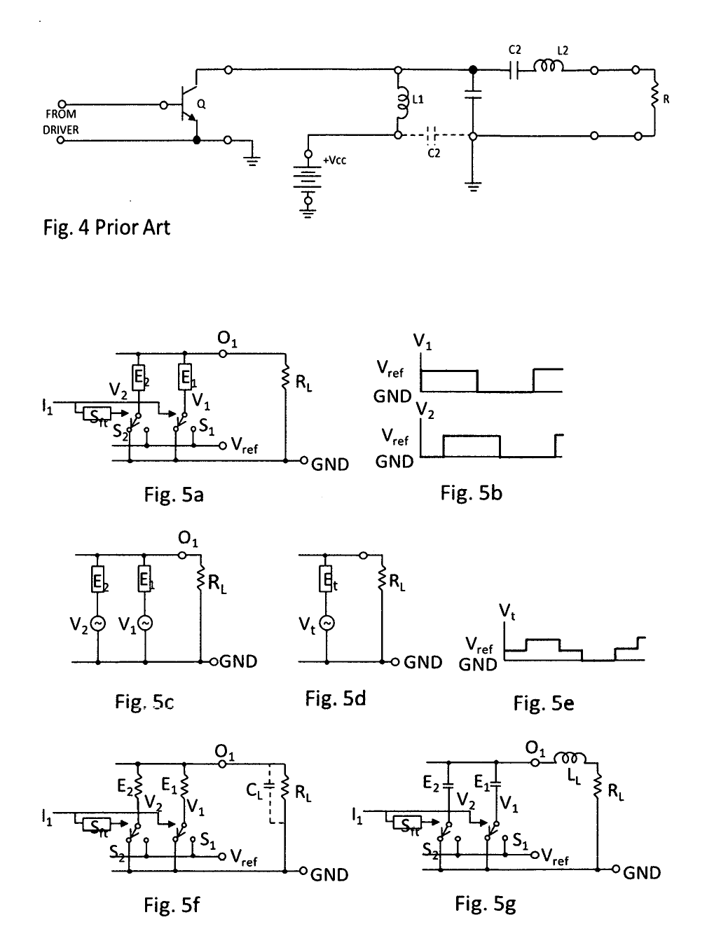

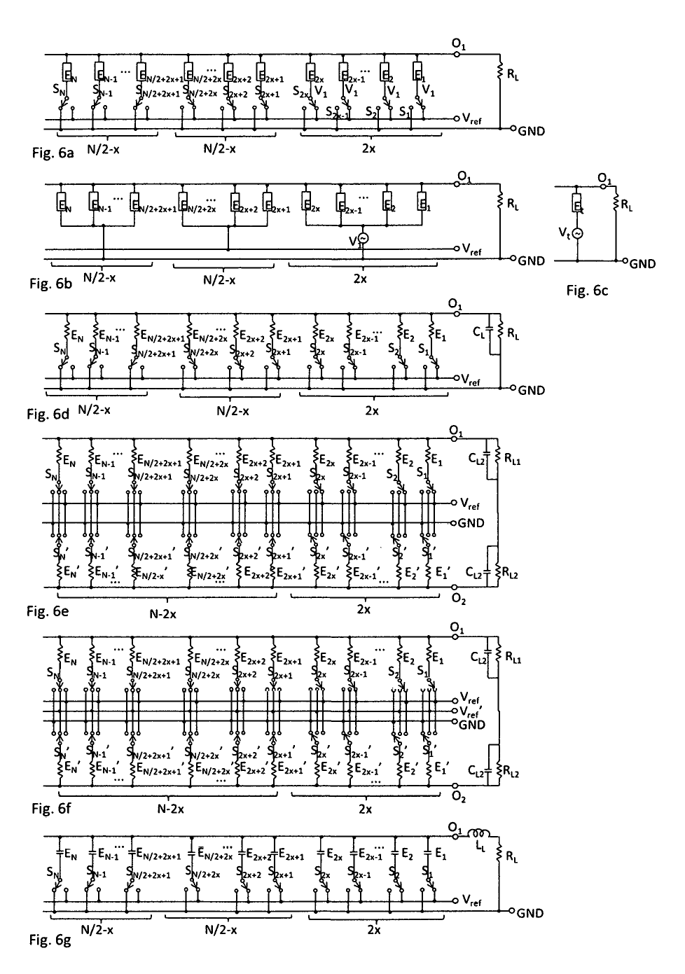

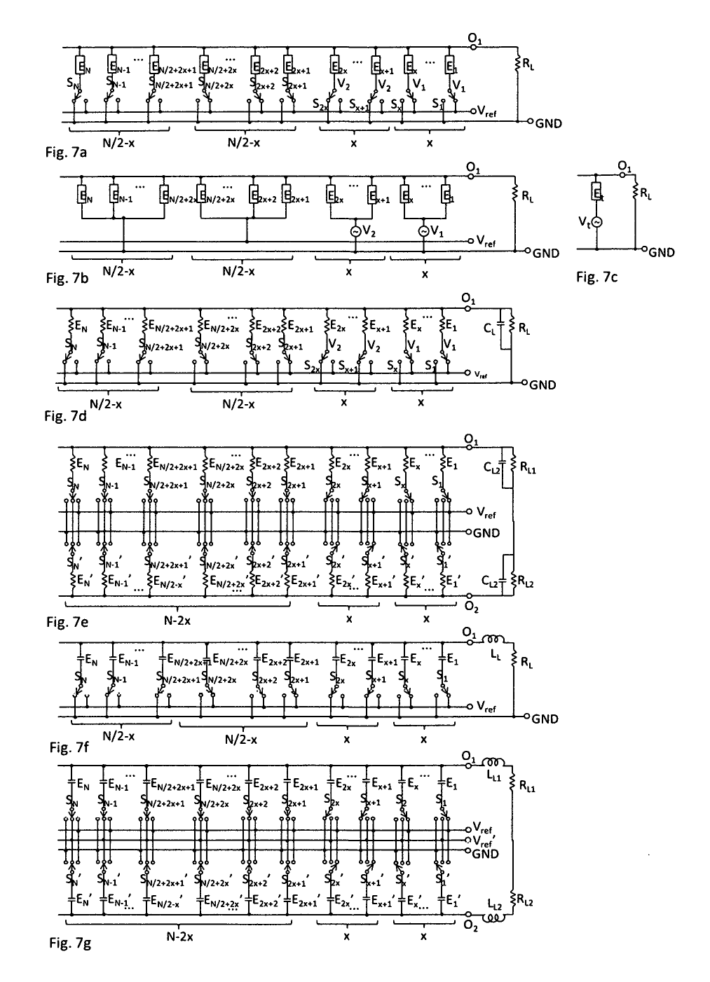

### DESCRIPTION OF REFERENCE SIGNS

E₁ to E_{N} N pieces of physical quantity elements

E₁′ to E_{N}′ N pieces of physical quantity elements

S₁ to Sₙ N pieces of switching elements

S₁′ to Sₙ′ N pieces of switching elements

Sft phase shifter

V_{ref}, V_{ref}′ reference voltage sources

GND reference voltage (ground)

O₁, O₂ output terminals

V₁, V₂ voltage sources

Vₜ equivalent voltage source

I₁ input signal

R_{L}, R_{L1}, R_{L2} load resistors

C_{L}, C_{L1}, C_{L2} capacitors

L_{L}, L_{L1}, L_{L2} inductor

1. A power output circuit in which one ends of a plurality of physical quantity elements are commonly connected to an output terminal and the other ends of the physical quantity elements are each switchably connected to a first or second reference voltage source via a corresponding one of switching elements, comprising:
a switch control circuit,
wherein the switch control circuit performs such control that a predetermined number of switching elements are alternately operated while the remaining number of switching elements are connected to any of the reference voltage source and a midpoint potential thereof or a switching element configured to interconnect between the physical quantity elements is added.

2. The power output circuit in which two power output circuits according to claim 1 are in differential connection, comprising:
a switch control circuit configured to commonly connect the remaining number of switching elements, thereby generating the midpoint potential.

3. The power output circuit in which two power output circuits according to claim 1 are in differential connection, comprising:
a switch control circuit,
wherein the switch control circuit uses the switching element(s) for interconnection, thereby interconnecting corresponding ones of the physical quantity elements during differential operation.

4. The power output circuit according to claims 1, comprising:
a switch control circuit configured to alternately operate, with different phases, multiple groups obtained by division of the predetermined number of switching elements, or
a switch control circuit configured to perform control equivalent to the control of alternately operating the multiple groups.

5. The power output circuit according to claims 1, comprising:
a switch control circuit configured to the predetermined number of switching elements according to an input digital baseband signal.

6. The power output circuit or the power output circuit including a modulator according to claims 1, wherein
each physical quantity element is a resistor, and
a capacitor is added in parallel with a load.

7. The power output circuit or the power output circuit including a modulator according to claims 1 or, wherein
each physical quantity element is a capacitor, and
an inductor is added in series with a load.

8. A power output circuit in which one ends of a plurality of capacitors are commonly connected to an output terminal and the other ends of the capacitors are each switchably connected to a first or second reference voltage source via a corresponding one of switching elements, comprising:
a switch control circuit,
wherein the switch control circuit performs such control that a predetermined number of switching elements are alternately operated while the remaining number of switching elements are connected to any of the reference voltage sources.
